(19) United States
(12) Patent Application Publication
(10) Pub. No.: US 2022/0279139 A1
(43) Pub. Date: Sep. 1, 2022

(54) IMAGE SENSOR AND OPERATION METHOD OF IMAGE SENSOR

(71) Applicant: SK hynix Inc., Gyeonggi-do (KR)

(72) Inventors: Sung Uk SEO, Gyeonggi-do (KR); Min Seok SHIN, Gyeonggi-do (KR); Oh Jun KWON, Gyeonggi-do (KR); Han Sang KIM, Gyeonggi-do (KR); Kang Bong SEO, Gyeonggi-do (KR); Jeong Eun SONG, Gyeonggi-do (KR)

(21) Appl. No.: 17/369,420

(22) Filed: Jul. 7, 2021

(30) Foreign Application Priority Data
Feb. 26, 2021 (KR) 10-2021-0026455

(51) Int. Cl. H04N 5/363; H04N 5/3745; H04N 5/374; H03M 1/56

(52) U.S. Cl. CPC H04N 5/363; H04N 5/37455; H04N 5/3741; H03M 1/56

(57) ABSTRACT

An image sensor includes: a normal pixel which outputs pixel data; a plurality of dummy pixels each of which outputs a reset signal; and an analog-to-digital conversion circuit suitable for analog-to-digital converting the pixel data based on the pixel data and an average value of the reset signals.

### CROSS-REFERENCE TO RELATED APPLICATIONS

The present application claims priority of Korean Patent Application No. 10-2021-0026455, filed on Feb. 26, 2021, which is incorporated herein by reference in its entirety.

### BACKGROUND

### 1. Field

Various embodiments of the present invention relate to an image sensor.

### 2. Description of the Related Art

Recently, an image sensor that provides a three-dimensional (3D) distance image by simultaneously measuring a certain range of distances is being developed. Acquiring such distance image is based on Time-of-Flight (TOF) technology. According to the technology, distances may be measured by irradiating light from a light source near an image sensor and measuring the time taken for the light to be reflected off an object and return.

The TOF technology is largely divided into two methods. One is a direct method and the other is an indirect method. The direct method is to irradiate pulse-type light, measure the time taken for receiving the reflected light, and convert the measured time into distance. In the direct method, precision may be improved by making the pulse width as small as possible in consideration of the luminous flux. Also, the direct method requires very precise time measurement.

The indirect method does not directly measure the TOF but irradiates modulated light, measures the phase difference with the reflected light, and extracts the distance. To be specific, according to the indirect method, the distance to an object may be measured by sensing the reflected light with pixels that are activated at different times, and using the difference between the amounts of light received by the pixels that are activated at different times.

### SUMMARY

Embodiments of the present invention are directed to reducing noise of an image sensor.

In accordance with an embodiment of the present invention, an image sensor includes: a normal pixel which outputs pixel data; a plurality of dummy pixels each of which outputs a reset signal; and an analog-to-digital conversion circuit suitable for analog-to-digital converting the pixel data based on the pixel data and an average value of the reset signals.

In accordance with another embodiment of the present invention, an image sensor includes: a pixel array including a plurality of rows and a plurality of columns, where a plurality of dummy pixels are arranged in the columns of a dummy row among the rows and a plurality of normal pixels are arranged in the columns of each of the normal rows among the rows; a plurality of current sources coupled to respective output lines of the columns and each suitable for sinking a current from a corresponding output line among the output lines; an analog-to-digital conversion circuit suitable for performing an analog-to-digital conversion operation by using reset signals output from the respective dummy pixels to the respective output lines and pixel signals output from normal pixels of a selected normal row among the normal rows to the respective output lines; and a plurality of switches suitable for electrically connecting the output lines to each other in a section where the reset signals are output from the respective dummy pixels.

In accordance with yet another embodiment of the present invention, a method for operating an image sensor includes: outputting reset signals from a plurality of dummy pixels to a plurality of respective output lines; electrically connecting the output lines to each other; and auto-zeroing a plurality of comparators while voltages of the respective output lines and a ramp signal are applied to the respective comparators.

In accordance with still another embodiment of the present invention, an image sensor includes: a pixel array including rows and columns, the rows including a dummy pixel row; output lines coupled to the respective columns; a switching circuit configured to electrically connect the output lines to each other during an auto zeroing operation; and an analog-to-digital conversion circuit including comparators coupled to the respective output lines and configured to perform the auto zeroing operation on the comparators with reset signals provided from the dummy pixel row through the connected output lines.

### BRIEF DESCRIPTION OF THE DRAWINGS

FIG. 1 is a block diagram illustrating an image sensor 100 in accordance with an embodiment of the present invention.

FIG. 2 is a block diagram illustrating a normal pixel P_11 and a dummy pixel P_D1 shown in FIG. 1 in accordance with an embodiment of the present invention.

FIG. 3 is a block diagram illustrating an analog-to-digital conversion circuit 150 shown in FIG. 1 in accordance with an embodiment of the present invention.

FIG. 4 is a timing diagram illustrating an operation of the image sensor 100 shown in FIG. 1 in accordance with an embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

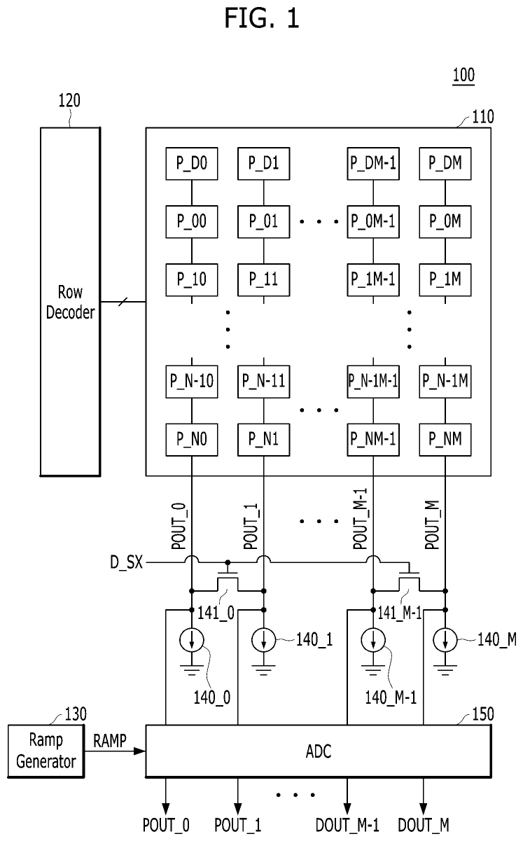

FIG. 1 is a block diagram illustrating an image sensor 100 in accordance with an embodiment of the present invention.

Referring to FIG. 1, the image sensor 100 may include a pixel array 110, a row decoder 120, a ramp generator 130, current sources 140_0 to 140_M, switches 141_0 to 141_M−1, and an analog-to-digital conversion circuit 150.

The pixel array 110 may include pixels that are arranged in a plurality of rows and a plurality of columns. Herein, it is illustrated that the pixel array includes one dummy row and N+1 normal rows and includes M+1 columns, where N and M are arbitrary integers which are equal to or greater than 1. The uppermost row of the pixel array 110 may be a dummy row and dummy pixels P_D0 to P_DM may be arranged in the columns of the dummy row. Normal pixels P_00 to P_NM may be arranged in the columns of each of the normal rows.

For controlling the pixels of the pixel array 110, the row decoder 120 may generate various signals such as reset control signals RX_0 to RX_N, transfer signals TX_0 to TX_N, selection signals SX_0 to SX_N.

The ramp generator 130 may generate a ramp signal RAMP to be used for an analog-to-digital conversion operation of the analog-to-digital conversion circuit 150.

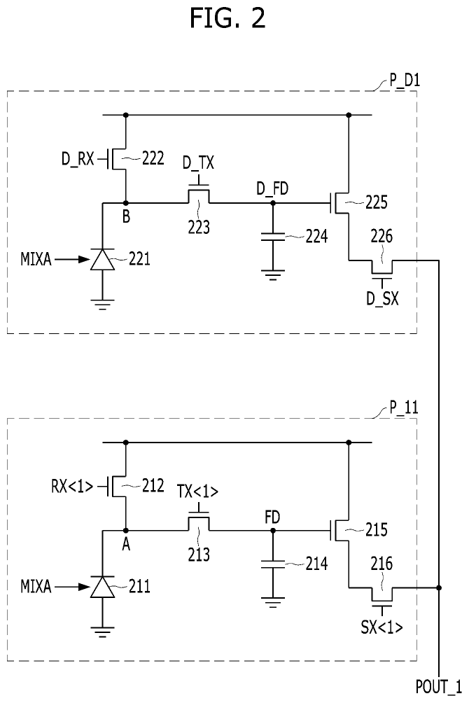

The current sources 140_0 to 140_M may sink a current from output lines POUT_0 to POUT_M of the pixel array 110. The voltage level of the output lines POUT_0 to POUT_M may be determined by the amount of current sourced from the pixels selected among the pixels of the pixel array to the output lines POUT_0 to POUT_M and the amount of sinking current of the current sources 140_0 to 140_M. The current sources 140_0 to 140_M may form a source follower of the amplifying elements (e.g., refer to elements 215 and 225 in FIG. 2) of the pixel array 110.

The switches 141_0 to 141_M−1 may electrically connect the output lines POUT_0 to POUT_M in a section where reset signals are output from the dummy pixels P_D0 to P_DM of the pixel array 110 to the output lines POUT_0 to POUT_M. The switches 141_0 to 141_M−1 may be turned on in response to a dummy row selection signal D_SX. Noise of the reset signal may be reduced by using the switches 141_0 to 141_M−1, which will be described later in detail.

The analog-to-digital conversion circuit 150 may perform an analog-to-digital conversion operation by using the reset signals, which correspond to the voltages of reset floating diffusion nodes and are output from the dummy pixels P_D0 to P_DM to the output lines POUT_0 to POUT_M, and the pixel signals, which correspond to the voltages of the floating diffusion nodes D_FD corresponding to the sensed light and are output from the normal pixels of a selected normal row among normal rows to the output lines POUT_0 to POUT_M. The analog-to-digital conversion circuit 150 may perform an auto-zeroing operation based on the reset signals and analog-to-digital converts the pixel signals.

FIG. 2 is a block diagram illustrating a normal pixel P_11 and a dummy pixel P_D1 shown in FIG. 1 in accordance with an embodiment of the present invention. In FIG. 2, the normal pixel P_11 and the dummy pixel P_D1 positioned in the same column of the pixel array 110 are illustrated. The remaining normal pixels and the dummy pixels of the pixel array 110 may be formed in the same manner as in FIG. 2.

Referring to FIG. 2, the normal pixel P_11 may include a photo detector 211, a reset transistor 212, a transfer transistor 213, a capacitor 214, a driving transistor 215, and a selection transistor 216.

The photo detector 211 may perform a photoelectric conversion function. The photo detector 111 may be realized by using at least one among a photo diode, a photo transistor, a photo gate, a pinned photo diode, and a combination thereof. The photo detector 211 may determine the exposure in response to a modulation signal MIXA. For example, the photo detector 211 may detect light in a section where the modulation signal MIXA is at a high level.

The reset transistor 212 may be initialized by supplying a power voltage to a node A to which the photo detector 211 is coupled in response to a reset signal RX<1>. The transfer transistor 213 may electrically connect the node A and the floating diffusion node FD to each other in response to a transfer signal TX<1>. The floating diffusion node FD may be a node in which charges corresponding to a chip detected by the photo detector 211 or charges corresponding to an initialization voltage are accumulated. A capacitor 214 may be coupled to the floating diffusion node FD. The driving transistor 215 may include a gate which is coupled to the floating diffusion node FD, and a drain and a source which are coupled between the power source voltage terminal and the selection transistor 216. The driving transistor 215 may supply a current to the selection transistor 216 according to the voltage level of the floating diffusion node FD. The selection transistor 216 may transfer the current transferred from the driving transistor 215 to an output line POUT_1 when a selection signal SX<1> is activated.

Just like the normal pixel P_11, the dummy pixel P_D1 may include a dummy photo detector 221, a dummy reset transistor 222, a dummy transfer transistor 223, a dummy capacitor 224, a dummy driving transistor 225, and a dummy selection transistor 226. The dummy pixel P_D1 may read a reset level by replicating the normal pixel P_11. Here, it is illustrated that the dummy pixel P_D1 and the normal pixel P_11 have the same structure. However, if necessary, some of the elements of the normal pixel P_11 may be omitted to form a dummy pixel P_D1. Since the dummy pixel P_D1 is used to output a reset signal corresponding to the reset voltage of the floating diffusion node D_FD, the dummy reset signal D_RX and the dummy transfer signal D_TX that control the dummy pixel P_D1 may be fixed at the level of the power source voltage. The dummy selection signal D_SX may be a signal that is activated in a section where a signal is output from the dummy pixel to the output line POUT_1, and the dummy selection signal D_SX may be generated by the row decoder 120.

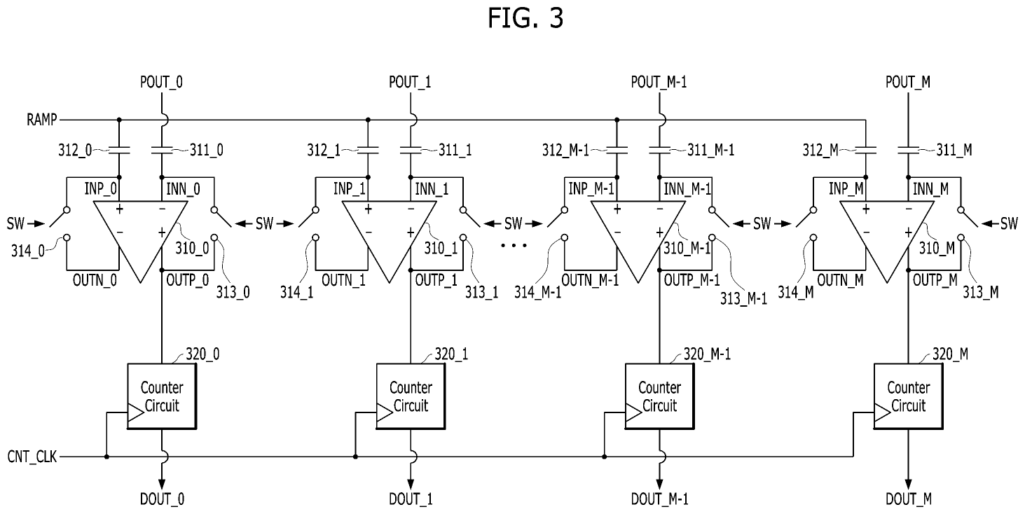

FIG. 3 is a block diagram illustrating an analog-to-digital conversion circuit 150 shown in FIG. 1 in accordance with an embodiment of the present invention.

Referring to FIG. 3, the analog-to-digital conversion circuit 150 may include a plurality of comparators 310_0 to 310_M and a plurality of counter circuits 320_0 to 320_M. The comparators 310_0 to 310_M and the counter circuits 320_0 to 320_M may respectively correspond to the output lines POUT_0 to POUT_M, and simultaneously analog-to-digital convert the signals that are output from the output lines POUT_0 to POUT_M.

The comparators 310_0 to 310_M may receive the signals of the output lines POUT_0 to POUT_M through the capacitors 311_0 to 311_M at the input terminals INN_0 to INN_M, respectively, and receive a ramp signal RAMP through the capacitors 312_0 to 312_M at the input terminals INP_0 to INP_M, respectively. The comparators 310_0 to 310_M may generate high-level signals of the output terminals OUTP_0 to OUTP_M when the voltage levels of the input terminals INP_0 to INP_M among the input terminals INN_0 to INN_M and INP_0 to INP_M are high. When the voltage levels of the input terminals INN_0 to INN_M among the input terminals INN_0 to INN_M and INP_0 to INP_M are high, the comparators 310_0 to 310_M may generate the signals of the output terminals OUTP_0 to OUTP_M at a low level. The switches 313_0 to 313_M and 314_0 to 314_M may be turned on during an auto-zeroing operation of the comparators 310_0 to 310_M to short the input terminals INN_0 to INN_M and the output terminals OUTP_0 to OUTP_M of the comparators 310_0 to 310_M and to short the input terminals INP_0 to INP_M and the output terminals OUTN_0 to OUTN_M.

The counter circuits 320_0 to 320_M may count a counting clock CNT_CLK in response to the signals of the output terminals OUTP_0 to OUTP_N of the comparators 310_0 to 310_M to generate digital codes DOUT_0 to DOUT_M.

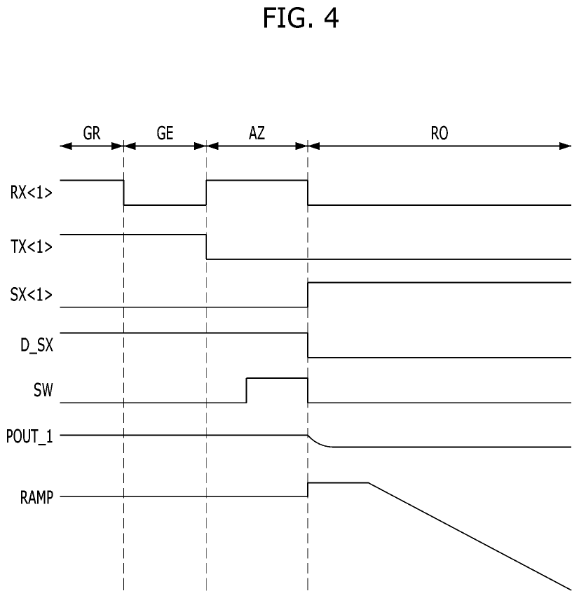

FIG. 4 is a timing diagram illustrating an operation of the image sensor 100 shown in FIG. 1 in accordance with an embodiment of the present invention. FIG. 4 illustrates a process of reading a pixel signal of a first normal row including the normal pixel P_11.

Referring to FIG. 4, first, a global reset operation may be performed. In a global reset operation section GR, a reset signal RX<1> and a transfer signal TX<1> may be activated to a high level, and the reset transistor 212 and the transfer transistor 213 of the normal pixel P_11 may be turned on to reset the floating diffusion node FD. Since the dummy reset signal D_RX and the dummy transfer signal D_TX of the dummy pixel P_D1 are fixed at the level of the power source voltage, the floating diffusion node D_FD of the dummy pixel P_D1 may be in a reset state continuously.

In a global exposure section GE after the global reset operation section GR, the reset signal RX<1> may be deactivated to a low level and the transfer signal TX<1> may be activated to a high level to turn off the reset transistor 212 of the pixel P_11 and turn on the transfer transistor 213. Accordingly, the charges of the photo detector 211, that is, the charges corresponding to the detected light, may be transferred to and stored in the floating diffusion node FD.

In an auto-zeroing operation section AZ, the reset signal RX<1> may be activated to a high level and the transfer signal TX<1> may be deactivated to a low level. Since the transfer transistor 213 of the normal pixel P_11 is turned off, the charges of the photo detector 211 may be continuously stored in the floating diffusion node FD. In the auto-zeroing operation section AZ, the dummy selection signal D_SX may be activated to a high level and the selection signal SX<1> may be deactivated to a low level to output the reset level stored in the floating diffusion node D_FD of the dummy pixel P_D1 through the output line POUT_1. In a portion of the auto-zeroing operation section AZ, the switch control signal SW may be activated to a high level to turn on the switches 313_1 and 314_1, and an auto-zeroing operation may be performed to short the input terminals INN_1 and INP_1 and the output terminals OUTP_1 and OUTN_1 of the comparator 310_1. In other words, the reset signal of the dummy pixel P_D1 may be applied to the input terminal INN_1 of the comparator 310_1 through the capacitor 311_1, and the comparator 310_1 may be auto-zeroed while the ramp signal RAMP is applied to the input terminal INP_1 through the capacitor 312_1.

Since the reset signal of the dummy pixel P_D1 is output to the output line POUT_1 through the dummy selection transistor 226, the level of the reset signal may be greatly affected by the random variation of a threshold voltage of the dummy selection transistor 226. In order to reduce the random variation of the threshold voltage of the dummy selection transistor 226, the size of the dummy selection transistor 226 has to be increased, which may be done by the switches 141_0 to 141_M−1. Since the dummy selection signal D_SX is activated to a high level during an auto-zeroing operation section, the switches 141_0 to 141_M−1 may be turned on to electrically connect all the output lines POUT_0 to POUT_M to each other in a section where reset signals from the dummy pixels P_D0 to P_DM are output to the output lines POUT_0 to POUT_M. In other words, all the output lines POUT_0 to POUT_M may be electrically connected to each other in a section where the dummy selection transistors of all the dummy pixels P_D0 to P_DM simultaneously output the reset signals to the output lines POUT_0 to POUT_M. Accordingly, random variation of the threshold voltage of the dummy selection transistors of the dummy pixels P_D0 to P_DM may be offset. In other words, the average value of the reset signals output from the dummy pixels P_D0 to P_DM may be applied to the comparators 310_0 to 310_M to auto-zero the comparators 310_0 to 310_M.

In the read-out section RO, the dummy selection signal D_SX may be deactivated to a low level and the selection signal SX<1> may be activated to a high level. Therefore, in the read-out section RO, a pixel signal corresponding to the voltage level of the floating diffusion node FD of the normal pixel P_11 may be output to the output line POUT_1. In the drawing, it may be seen that the voltage level of the output line POUT_1 decreases. The voltage level of the output line POUT_1 may fall as much as the difference between the voltage level of the reset signal output from the dummy pixel P_D1 and the voltage level of the pixel signal output from the normal pixel P11.

In the read-out section RO, a ramping operation in which the level of the ramp signal RAMP rises and then falls may be performed. When the ramp signal RAMP rises, the voltage level of the input terminal INP_1 of the comparator 310_1 may be higher than the voltage level of the input terminal INN_1, so that the output OUTP_1 of the comparator 310_1 may be at a high level. From a moment when the ramp signal (RAMP) falls to a moment when the voltage level of the input terminal INP_1 becomes lower than the voltage level of the input terminal INN_1, that is, to a moment when the output OUTP_1 of the comparator 310_1 transitions from high to low, the counter circuit 320_1 may generate a digital code DOUT_1 by counting the number of times that the counting clock CNT_CLK is activated. The digital code DOUT_1 may be obtained by analog-to-digital converting a value corresponding to the difference between the pixel signal output from the normal pixel P_11 and the reset signal output from the dummy pixel P_D1.

According to the embodiment of the present invention, noise of an image sensor may be reduced.

While the present invention has been described with respect to the specific embodiments, it will be apparent to those skilled in the art that various changes and modifications may be made without departing from the spirit and scope of the invention as defined in the following claims. Furthermore, the embodiments may be combined to form additional embodiments.

What is claimed is:

1. An image sensor, comprising:
a normal pixel which outputs pixel data;
a plurality of dummy pixels each of which outputs a reset signal; and
an analog-to-digital conversion circuit suitable for analog-to-digital converting the pixel data based on the pixel data and an average value of the reset signals.

2. The image sensor of claim 1,
wherein the dummy pixels simultaneously output the respective reset signals, and
wherein output terminals of the dummy pixels are coupled to each other in a section where the reset signals are simultaneously output.

3. An image sensor, comprising:
a pixel array including a plurality of rows and a plurality of columns, where a plurality of dummy pixels are arranged in the columns of a dummy row among the rows and a plurality of normal pixels are arranged in the columns of each of the normal rows among the rows;
a plurality of current sources coupled to respective output lines of the columns and each suitable for sinking a current from a corresponding output line among the output lines;
an analog-to-digital conversion circuit suitable for performing an analog-to-digital conversion operation by using reset signals output from the respective dummy pixels to the respective output lines and pixel signals output from normal pixels of a selected normal row among the normal rows to the respective output lines; and
a plurality of switches suitable for electrically connecting the output lines to each other in a section where the reset signals are output from the respective dummy pixels.

4. The image sensor of claim 3,
wherein when a dummy row selection signal is activated, the reset signals are output from the respective dummy pixels to the respective output lines, and
wherein the switches are turned on when the dummy row selection signal is activated.

5. The image sensor of claim 3, wherein the analog-to-digital conversion circuit includes:
a plurality of comparators corresponding to the respective output lines and each suitable for operating by receiving a ramp signal and a signal from a corresponding output line of the output lines; and
a plurality of counter circuits each suitable for generating a digital code in response to an output of a corresponding comparator among the comparators.

6. The image sensor of claim 5,
wherein the comparators are auto-zeroed in a section where the reset signals are output to the respective output lines, and
wherein the digital code is generated in response to the output of the corresponding comparator in a section where the pixel signals are output to the respective output lines.

7. The image sensor of claim 3, wherein each of the normal pixels includes:
a photo detector coupled to a first node;
a reset transistor suitable for resetting the first node in response to a reset control signal;
a transfer transistor suitable for electrically connecting the first node and the floating diffusion node to each other in response to a transfer signal;
a capacitor coupled to the floating diffusion node;
a driving transistor suitable for supplying a current in response to a voltage of the floating diffusion node; and
a selection transistor suitable for outputting the current supplied by the driving transistor to a corresponding output line of the output lines in response to a row selection signal.

8. The image sensor of claim 7, wherein each of the dummy pixels includes:
a photo detector coupled to a second node;
a dummy reset transistor suitable for resetting the second node in response to a dummy reset signal;
a dummy transfer transistor suitable for electrically connecting the second node and a dummy floating diffusion node to each other in response to a dummy transfer signal;
a dummy capacitor coupled to the dummy floating diffusion node;
a dummy driving transistor suitable for supplying a current in response to a voltage of the dummy floating diffusion node; and
a dummy selection transistor suitable for outputting the current supplied by the dummy driving transistor to a corresponding output line of the output lines in response to a dummy row selection signal.

9. The image sensor of claim 8, wherein the dummy reset signal and the dummy transfer signal are maintained in an active state.

10. A method for operating an image sensor, comprising:
outputting reset signals from a plurality of dummy pixels to respective output lines;
electrically connecting the output lines to each other; and
auto-zeroing a plurality of comparators while voltages of the respective output lines and a ramp signal are applied to the respective comparators.

11. The method of claim 10, further comprising:
electrically disconnecting the output lines from each other after the auto-zeroing;
outputting pixel signals from a plurality of normal pixels to the respective output lines;
performing a ramping operation while voltages of the respective output lines and the ramp signal are applied to the respective comparators; and
generating a plurality of digital codes in response to respective outputs of the comparators during the ramping operation.

12. An image sensor comprising:
a pixel array including rows and columns, the rows including a dummy pixel row;
output lines coupled to the respective columns;
a switching circuit configured to electrically connect the output lines to each other during an auto zeroing operation; and
an analog-to-digital conversion circuit including comparators coupled to the respective output lines and configured to perform the auto zeroing operation on the comparators with reset signals provided from the dummy pixel row through the connected output lines.
